(19) United States
(12) Patent Application Publication
(10) Pub. No.: US 2026/0075770 A1
(43) Pub. Date: Mar. 12, 2026

(54) VAPOR CHAMBER HEAT SPREADER

(71) Applicant: International Business Machines Corporation, Armonk, NY (US)

(72) Inventors: Kalind BARAYA, West Lafayette, IN (US); Christine Louise Taylor, Poughkeepsie, NY (US); SHIDONG LI, Hopewell Junction, NY (US)

(21) Appl. No.: 18/826,998

(22) Filed: Sep. 6, 2024

(51) Int. Cl. H05K 7/20

(52) U.S. Cl. CPC H05K 7/2039; H05K 7/20336

(57) ABSTRACT

A vapor chamber heat spreader is provided that is integrated with a microelectronic device. The vapor chamber heat spreader of the present application facilitates heat spreading and heat removal from the microelectronic device, while having an increased dry out limit that is significantly greater than conventional vapor chambers. The increased dry out limit of the vapor chamber heat spreader of the present application is achieved by electrowetting using electrodes that are powered by the microelectronic device. The electrodes reroute the liquid to hot spots to avoid dry out.

### BACKGROUND

The present application relates to microelectronics, and more particularly to a vapor chamber heat spreader and to an assembly that includes a vapor chamber heat spreader that facilitates heat spreading and heat removal from a microelectronic device.

In the semiconductor industry, the removal of heat from semiconductor chips and systems continues to remain a technology challenge that can often limit performance and reliability. Heat generated during the operation of the semiconductor chips needs to be efficiently removed in order to minimize the rise in the temperature of the semiconductor chips. A variety of thermal management techniques have been used ranging from passive cooling for lower power chips, to air cooling facilitated by heat sinks for medium power chips and to liquid cooling for high power chips.

### SUMMARY

A vapor chamber heat spreader is provided that is integrated with a microelectronic device. The vapor chamber heat spreader of the present application facilitates heat spreading and heat removal from the microelectronic device, while having an increased dry out limit that is significantly greater than conventional vapor chambers. The increased dry out limit of the vapor chamber heat spreader of the present application is achieved by electrowetting using electrodes that are powered by the microelectronic device through the electrically conductive via structures. The electrodes reroute the liquid to hot spots to avoid dry out.

In one aspect of the present application, a vapor chamber heat spreader is provided. In one embodiment of the present application, the vapor chamber heat spreader includes a vapor core present in an interior of a semiconductor structure, a first hydrophobic layer located in the interior of the semiconductor structure and beneath the vapor core, a second hydrophobic layer located in the interior of the semiconductor structure and above the vapor core, and a plurality of electrodes and a plurality of electrically conductive via structures located in a bottom portion of the semiconductor structure. Each electrically conductive via structure of the plurality of electrically conductive via structures is in electrical contact with, and located beneath, one of the electrodes of plurality of electrodes and each electrically conductive via structure extends entirely through the bottom portion of the semiconductor structure.

In another aspect of the present application, an assembly is provided. In one embodiment of the present application, the assembly includes a microelectronic device attached to a vapor chamber heat spreader, the vapor chamber heat spreader includes a vapor core present in an interior of a semiconductor structure, a first hydrophobic layer located in the interior of the semiconductor structure and beneath the vapor core, a second hydrophobic layer located in the interior of the semiconductor structure and above the vapor core, and a plurality of electrodes and a plurality of electrically conductive via structures located in a bottom portion of the semiconductor structure. Each electrically conductive via structure of the plurality of electrically conductive via structures is in electrical contact with, and located beneath, one of the electrodes of plurality of electrodes and each electrically conductive via structure extends entirely through the bottom portion of the semiconductor structure.

### BRIEF DESCRIPTION OF THE DRAWINGS

FIG. 1 is a cross sectional view of a vapor chamber heat spreader in accordance with an embodiment of the present application.

FIG. 2 is a schematic illustrating the operation of a vapor chamber heat spreader in accordance with the present application.

FIGS. 3A-3D are cross sectional views of a process flow that can be used in forming a bottom portion of a vapor chamber heat spreader in accordance with an embodiment of the present application.

FIGS. 4A-4C are cross sectional views of a process flow that can be used in forming a top portion of a vapor chamber heat spreader in accordance with an embodiment of the present application.

FIG. 5 is a cross sectional view of a precursor vapor chamber heat spreader that is formed after bonding the top portion of the vapor chamber heat spreader shown in FIG. 4C and the bottom portion of the vapor chamber heat spreader shown in FIG. 3D together.

FIG. 6 is a cross sectional view of a vapor chamber heat spreader in accordance with the present application in contact with an end-of-the-line (EOL) layer of a microelectronic device.

FIGS. 7A-7B are cross sectional views of a process flow for forming an assembly in accordance with an embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

As integrated circuitry continues to scale to smaller and smaller feature dimensions and higher packaging density, the density of power consumption of a given microelectronic device within a given package tends to increase which, in turn, tends to increase the average junction temperature of the transistors in the microelectronic device. If the temperature of the microelectronic device becomes too high, the integrated circuits in the microelectronic device can be damaged and/or performance issues can arise. This issue is intensified when multiple microelectronic devices are incorporated into close proximity with each other notably, and when two or more microelectronic device are in close proximity of each other heat has to be dissipated from these devices. Thus, thermal transfer solutions such as, for example, heat spreaders have been utilized to remove the excess heat from the microelectronic devices.

Vapor chamber heat spreaders are planar heat pipes that spread heat from a concentrated heat source to a large-area heat sink with effective thermal conductivities. In the most basic configuration, the vapor chamber consists of a sealed container, a wick formed on the inside wall of the container, and a small amount of fluid that is in equilibrium with its own vapor. As the heat is applied to one side of the vapor chamber (i.e., an evaporator portion), the working fluid vaporizes and the vapor spreads to the entire inner volume and condenses over a much larger surface. The condensate is returned to the evaporator portion via capillary forces developed in the wick. Vapor chambers are generally used for high heat flux applications, or when genuine two-dimensional heat spreading is required. Vapor chambers can accept heat from a high heat flux source, and spread the heat uniformly over a large area.

Vapor chambers are passive heat spreaders which have found application in microelectronics as a way to mitigate hot spots in microelectronic devices by spreading heat away from such devices. In traditional vapor chambers, the dry out limit (i.e., maximum power dissipation) is one-to-two orders of magnitude less than the power levels observed in current microelectronic devices and packages that contain the same. There is thus a need for providing a vapor chamber that can be used as a heat spreader in microelectronic applications in which the dry out limit of the vapor chamber is significantly increased beyond that of conventional vapor chambers in which wicking is used as the primary means of heat spreading.

In the present application, a vapor chamber heat spreader is provided that is integrated with a microelectronic device. The vapor chamber heat spreader of the present application facilitates heat spreading and heat removal from the microelectronic device, while having an increased dry out limit that is significantly greater than conventional vapor chambers. For example, conventional vapor chambers at form factors used in first level packages are shown to have a dry out power between 1 W and 10 W. In the present application, the vapor chamber heat spreader using equivalent form factors has a dry out power which is one to two orders of magnitude greater than that of the conventional vapor chamber. The increased dry out power of the vapor chamber heat spreader of the present application is achieved by electrowetting using electrodes that are powered by the electronic device itself; the power is delivered from the electronic device to the electrodes by means of electrically conductive via structures. The electrodes reroute the liquid to hot spots to avoid dry out.

Electrowetting is a technique that can be used to change the wetting behavior (i.e., contact angle) of a sessile droplet and it is used to actuate liquid by creating an asymmetric electric field and a drop contact line. In the present application, the electrodes control liquid droplet spreading over a hydrophobic surface. This aspect of the present application will be described with respect to FIG. 2.

Throughout the present application, the term “microelectronic device” is used to describe extremely small electronic components, circuits, and systems that are fabricated on a scale of micrometers or smaller. The microelectronic device can include a single microelectronic device or a plurality of microelectronic devices which in some cases can be vertically stacked one on top the other. For example, the microelectronic device can be a single semiconductor chip (or die) or a plurality of semiconductor chips (or dies) that are stacked vertically one on top of the other (e.g., a 3D chip or a 3D die stack). The microelectronic device can be a component of a microelectronic package in which the vapor chamber heat spreader of the present application can be used. In such applications, the vapor chamber heat spreader of the present application can be used as a lid of the package.

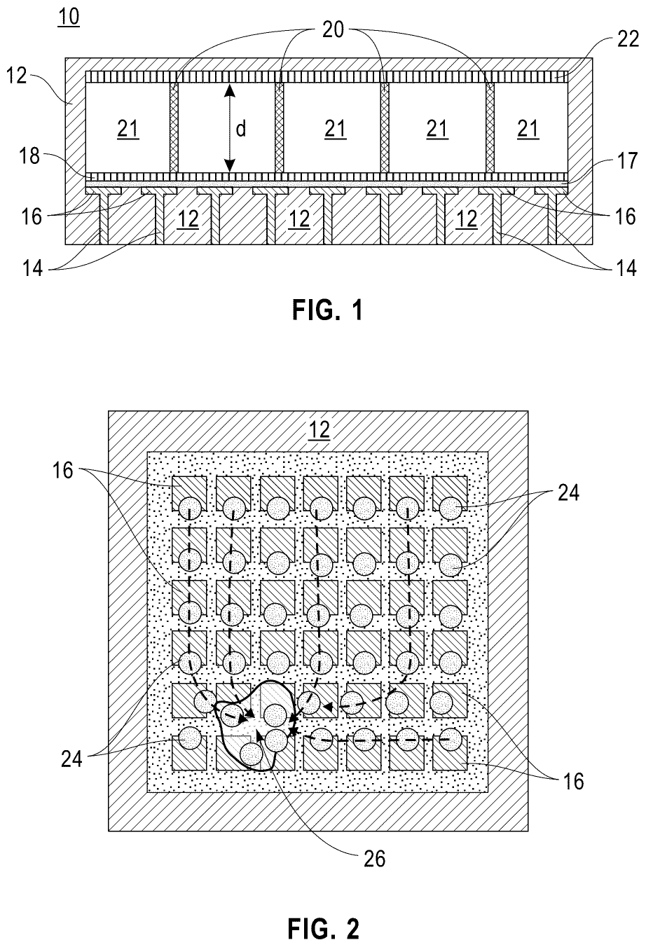

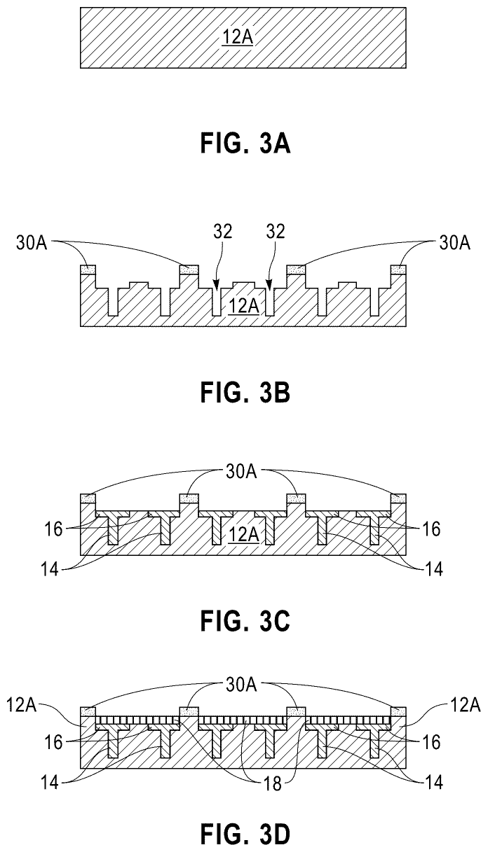

Referring first to FIG. 1, there is illustrated a vapor chamber heat spreader 10 in accordance with an embodiment of the present application. The vapor chamber heat spreader 10 includes a semiconductor structure 12 that includes a vapor core 21. The semiconductor structure 12 surrounds the vapor core 21 that is located in an interior of the semiconductor structure 12. The semiconductor structure 12 includes a bottom portion and a top portion that are bonded together. This aspect of the present application is not illustrated in FIG. 1, but will become more apparent when discussion is made to the process flow illustrated in FIGS. 3A-5. The semiconductor structure 12 can be composed of at least one semiconductor material. As used throughout the present application, the term “semiconductor material” denotes a material that has semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. Typically, the semiconductor structure 12 is composed entirely of a single semiconductor material such as, for example, Si.

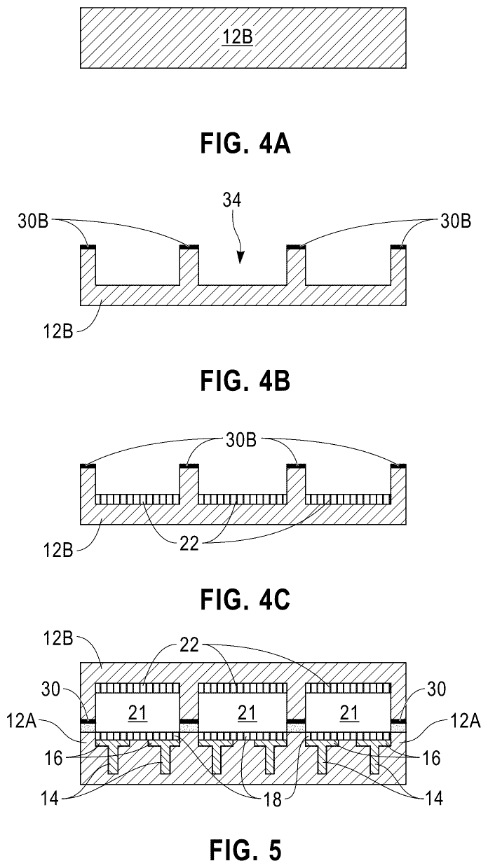

The vapor core 21 defines a cavity that is present in the interior of the semiconductor structure 12. As is illustrated in FIG. 1, the vapor core 21 is housed in the semiconductor structure 12 and the semiconductor structure 12 is located on top of, on bottom of, and along each sidewall of the vapor core 21. In embodiments, one or more support pillars 20 can be present in the vapor core 21. Each support pillar 20 is composed of a semiconductor material. The semiconductor material that provides each support pillar 20 is a compositionally same semiconductor material as used in forming a top portion of the semiconductor structure 12 (i.e. second semiconductor substrate 12B shown in FIG. 4B). Each support pillar 20 provides structural support to the vapor chamber heat spreader of the present application, and can function as a wick structure because condensate from a second hydrophobic layer 22 can travel down the support pillar 20 using capillary action. Support pillars 20 can be optional, but it is desirable to include such support pillars 20 in the vapor chamber heat spreader of the present application for both structural support and as an additional means to spread the heat.

The vapor core 21 is located between a first hydrophobic layer 18 and the second hydrophobic layer 22, each of the first and second hydrophobic layers is in the interior of the semiconductor structure 12. The first hydrophobic layer 18 is composed of a first hydrophobic material. The second hydrophobic layer 22 is composed of a second hydrophobic material which can be compositionally the same as, or compositionally different from, the first hydrophobic material that provides the first hydrophobic layer 18. The first hydrophobic material and the second hydrophobic material are typical hydrophobic, or water-resistant polymers, which are insoluble in water or other polar solvents and can include, for example, acrylics, epoxies, polyethylene, polystyrene, polyvinylchloride, polytetrafluorethylene, polydimethylsiloxane, polyesters, and polyurethanes. Some specific examples of hydrophobic, or water-resistant polymers that can be used in the present application include, but are not limited to, polydimethylsiloxane (PDMS), polytetrafluoroethylene (PTFE), and amorphous fluoropolymers.

The support pillar 20 extends from a topmost surface of the opening present in the semiconductor structure 12 to the bottommost surface of the opening present in the semiconductor structure 12. In the present application, the distance, d, between an inner horizontal surface of the first hydrophobic layer 18 and an inner horizontal surface of the second hydrophobic layer 22 defines a height of the vapor core 21. In the present application, the inner horizontal surface is a surface that is located closest to the vapor core 21 as compared to an outer horizontal surface that is located a further distance from the vapor core 21 as compared to the inner horizontal surface. The vertical height of the support pillar 20 is d plus the thickness of the dielectric layer 17 (if the same is present) plus the thickness of the first hydrophobic layer 18 plus the thickness of the second hydrophobic layer 22. It is noted that in the cross sectional view of FIG. 1, each support pillar 20 lies “behind” dielectric layer 17, the first hydrophobic layer 18 and the second hydrophobic layer 22.

In embodiments of the present application, the outer horizontal surface of the second hydrophobic layer 22 is in direct physical contact with a top wall of the semiconductor structure 12. Each of first hydrophobic layer 18 and the second hydrophobic layer 22 has a length that extends from one inner sidewall of the semiconductor structure 12 to another inner sidewall of the semiconductor structure 12.

In some embodiments and as is illustrated in FIG. 1, the vapor chamber heat spreader 10 can further include dielectric layer 17 located between the first hydrophobic layer 18 and electrodes 16. In such embodiments, the dielectric layer 17 is in direct physical contact with an outer horizontal surface of the first hydrophobic layer 18 and with each of the underlying electrodes 16. In some embodiments, the dielectric layer 17 is omitted and the outer horizontal surface of the first hydrophobic layer 18 is in direct physical contact with each of the underlying electrodes 16. When present, the dielectric layer 17 is composed of a dielectric material such as, for example, silicon dioxide, silicon nitride and/or silicon oxynitride.

Each electrode 16 is in direct physical contact with an electrically conductive via structure 14 that extends entirely through a lower portion of the semiconductor structure 12. Each electrode 16 and each electrically conductive via structure 14 is composed of an electrically conductive metal or an electrically conductive metal alloy. Exemplary electrically conductive metals include, but are not limited to, Cu, W, Al, Co, or Ru. An exemplary electrically conductive metal alloy is a Cu—Al alloy. Typically, Cu is used in providing both the electrodes 16 and the electrically conductive via structures 14.

In some embodiments of the present application, the electrodes 16 can be composed of a compositionally same electrically conductive metal or electrically conductive metal alloy (i.e., electrically conductive material) as the electrically conductive via structures 14. In such an embodiment, no material interface is present between the electrodes 16 and the electrically conductive via structures 14. In some embodiments of the present application, the electrodes 16 can be composed of a compositionally different electrically conductive material than the electrically conductive via structures 14. In such an embodiment, a material interface is present between the electrodes 16 and the electrically conductive via structures 14.

The electrodes 16 and the electrically conductive via structures 14 are embedded in a lower portion of the semiconductor substrate 12, however a surface of each of the electrically conductive via structures 14 is available to be electrically connected to an underlying microelectronic device, and a surface of each of the electrodes 16 is available to be in physical contact with either the dielectric layer 17 (when the same is present) or the first hydrophobic layer 18 (when dielectric layer 17 is not present).

In the present application, the electrodes 16 are powered by a microelectronic device that is attached to the vapor chamber heat spreader 10 through the electrically conductive via structures 14 and are configured so as to reroute liquid to hot spots to avoid dry out. This aspect of the present application is discussed in greater detail by referring to the schematic shown in FIG. 2 which illustrates the operation of a vapor chamber heat spreader 10 in accordance with the present application. Notably, FIG. 2 illustrates a bottom portion of the semiconductor structure 12 of a vapor chamber heat spreader 10 in accordance with the present application that includes electrodes 16 that are powered through the electrically conductive vias 14 (not illustrated in the schematic shown in FIG. 2) by a microelectronic device (as not illustrated in FIG. 2), and first hydrophobic layer 18. It is noted that the first hydrophobic layer 18 would be located on top of the electrodes 16 however this aspect of the present application is not illustrated in FIG. 2 so as to emphasize the electrowetting aspect of the present application. In FIG. 2, liquid droplets 24 are present and each of the liquid droplets 24 is rerouted to hot spot 26 as is shown in FIG. 2. Thus dry out is substantially eliminated, and an increased dry out limit is obtained, using the vapor chamber heat spreader 10 in accordance with the present application.

Notably, FIG. 1 illustrates a vapor chamber heat spreader 10 in accordance with an embodiment of the present application. The vapor chamber heat spreader includes vapor core 21 present in an interior of semiconductor structure 12, first hydrophobic layer 18 is located in the interior of the semiconductor structure 12 and beneath the vapor core 21, second hydrophobic layer 22 is located in the interior of the semiconductor structure 12 and above the vapor core 21, and a plurality of electrodes (i.e., electrodes 16) and a plurality of electrically conductive via structures (i.e., electrically conducive via structures 14) are located in a bottom portion of the semiconductor structure 12. Each of the electrically conductive via structure 14 of the plurality of electrically conductive via structures is in electrical contact with, and located beneath, one of the electrodes 16 of plurality of electrodes and each electrically conductive via structure 14 extends entirely through the bottom portion of the semiconductor structure 12. In the vapor chamber heat spreader 10 of the present application (and as illustrated in FIG. 2), liquid is guided to hotspots by application of electrowetting which is controlled by each electrically connected electrode/electrically conductive via structure combination. Thus, the vapor chamber heat spreader 10 of the present application can facilitate heat spreading and heat removal from a microelectronic device, while having an increased dry out limit that is significantly greater than conventional vapor chambers. The increased dry out limit of the vapor chamber heat spreader 10 of the present application is achieved by electrowetting using electrodes that are powered by electrically conductive via structures.

In some embodiments, each of the electrodes 16 of the plurality of electrodes is in direct physical contact with the first hydrophobic layer 18.

In some embodiments, the vapor chamber heat spreader 10 of the present application further includes dielectric layer 17 located between the first hydrophobic layer 18 and the plurality of electrodes.

In embodiments, the vapor chamber heat spreader 10 of the present application includes a support pillar 20 present in the vapor core 21. The support pillar 20 provides structural support and can serve as a wicking aid in the vapor chamber heat spreader 10 of the present application as described above.

In some embodiments, the plurality of electrodes and the plurality of electrically conductive via structures are composed of a same electrically conductive metal or electrically conductive metal alloy.

In some embodiments, the plurality of electrodes are composed of a first electrically conductive material, and the plurality of electrically conductive via structure are composed of a second electrically conductive material in which the second electrically conductive material is compositionally different from the first electrically conductive material.

In embodiments, the second hydrophobic layer 22 is in direct physical contact with a top portion of the semiconductor structure 12. The second hydrophobic layer 22 helps in returning condensate to the bottom portion of the vapor chamber via the support pillars 20.

In some embodiments, the bottom portion of the semiconductor structure 12 is composed of first semiconductor substrate 12A (see, for example, FIG. 3A) and the semiconductor structure has a top portion composed of second semiconductor substrate 12B (see, for example, FIG. 4A), and the first semiconductor substrate 12A is in direct physical contact with the second semiconductor substrate 12B; such an embodiment is illustrated in FIG. 1. The contact between the first semiconductor substrate 12A and the second semiconductor substrate 12B is for hermetically bonding the two substrates together.

In some embodiments, the bottom portion of the semiconductor structure 12 is composed of first semiconductor substrate 12A (see, for example, FIG. 3A) and the semiconductor structure 12 has a top portion composed of second semiconductor substrate 12B, and the first semiconductor substrate 12A is spaced apart from the second semiconductor substrate 12B by a dielectric-to-dielectric bonded structure 30 (See, for example, FIG. 5). In some embodiments, silicon oxide is used as the material for the dielectric-to-dielectric bonded structure 30.

Referring now to FIGS. 3A-3D, there are illustrated a process flow that can be used in forming a bottom portion of a vapor chamber heat spreader in accordance with an embodiment of the present application. Notably, FIG. 3A illustrates a first semiconductor substrate 12A that can be used in the present application. The first semiconductor substrate 12A is composed of a first semiconductor material such as, for example, Si. FIG. 3B shows the first semiconductor substrate 12A illustrated in FIG. 3A after forming a first patterned dielectric layer 30A on the first semiconductor substrate 12A and then forming combined via and line openings 32A in the first semiconductor substrate 12A. The first patterned dielectric layer 30A is composed of a first bonding dielectric material such as, for example, silicon oxide. The first patterned dielectric layer 30A can be formed by a deposition process (e.g., chemical vapor deposition (CVD), plasma enhanced chemical vapor deposition (PECVD), atomic layer deposition (ALD) or physical vapor deposition (PVD)) or by a thermal growth process such as, for example, thermal oxidation and/or thermal nitridation, followed by lithographic patterning of the as-deposited or thermally grown dielectric layer. The lithographic patterning which includes an etch forms via openings in the as-deposited or thermally grown dielectric layer. Another etch (or the same etch) can then be used to transfer the pattern (i.e., via openings) into the first semiconductor substrate 12A thus forming via openings in the first semiconductor substrate 12A. A second lithographic patterning process can be used to form line openings into previously patterned as-deposited or thermally grown dielectric layer and into an upper portion of the first semiconductor substrate 12A. Each line opening provided in the upper portion of the first semiconductor substrate 12A is interconnected to a via opening.

Next, and as shown in FIG. 3C, an electrically conductive via structure 14 and an electrode 16 are formed into each of the combined via and line openings 32A. In one embodiment, the electrically conductive via structure 14 and the electrode 16 are formed simultaneously by deposition of an electrically conductive metal or an electrically conductive material alloy, followed a planarization process such as, for example (chemical mechanical polishing (CMP)), and then by an etch back process. In another embodiment, the electrically conductive via structure 14 is formed first by deposition of a first electrically conductive metal or a first electrically conductive material alloy, followed a planarization process such as, for example (chemical mechanical polishing (CMP)), and then by an etch back process, and then the electrode 16 is formed by deposition of a second electrically conductive metal or a second electrically conductive material alloy (the second electrically conductive material is compositionally different from the first electrically conductive material), followed a planarization process and then by an etch back process. In either embodiment, deposition of the electrically conductive material (i.e., electrically conductive metal or electrically conductive metal alloy) can include, CVD, PECVD, sputtering or plating,

Next, and as is illustrated in FIG. 3D, first hydrophobic layer 18 is formed on the electrodes 16 and a portion of the first semiconductor substrate 12A by a deposition process such as, for example, CVD, PECVD, or spin-coating. In some embodiments, and prior to forming the first hydrophobic layer 18, dielectric layer 17 can be formed on the electrodes 16 and a portion of the first semiconductor substrate 12A by a deposition process such as, for example, CVD, PECVD, or spin-coating, followed by the formation of the first hydrophobic layer 18.

Referring now to FIGS. 4A-4C, there are illustrated a process flow that can be used in forming a top portion of a vapor chamber heat spreader in accordance with an embodiment of the present application. Notably, FIG. 4A illustrates a second semiconductor substrate 12B that can be used in the present application. The second semiconductor substrate 12B is composed of a second semiconductor material such as, for example, Si. Note that the second semiconductor material that provides the second semiconductor substrate 12B can be compositionally the same as, or compositionally different from, the first semiconductor material that provides the first semiconductor substrate 12A. FIG. 4B shows the second semiconductor substrate 12B illustrated in FIG. 4A after forming a second patterned dielectric layer 30B on the second semiconductor substrate 12B and then forming cavities 34 in the second semiconductor substrate 12B. Note that in FIG. 4B, the non-etched portion of the second semiconductor substrate 12B in the middle of the illustrated structure represents the support pillars 20 shown in FIG. 1 above. The second patterned dielectric layer 30B is composed of a second bonding dielectric material such as, for example, silicon oxide. The second bonding dielectric material that provides the second patterned dielectric layer 30B can be compositionally the same as, or compositionally different from, the first bonding dielectric material that provides the first patterned dielectric layer 30A. The second patterned dielectric layer 30B can be formed by a deposition process (e.g., CVD, PECVD, ALD or PVD) or by a thermal growth process such as, for example, thermal oxidation and/or thermal nitridation, followed by lithographic patterning of the as-deposited or thermally grown dielectric layer. The lithographic patterning which includes an etch forms openings in the as-deposited or thermally grown dielectric layer. Another etch (or the same etch) can then be used to transfer the pattern (i.e., openings) into the second semiconductor substrate 12B thus forming cavities 36 in the second semiconductor substrate 12B. Next, and as is illustrated in FIG. 4C, second hydrophobic layer 22 is formed at the bottom of each of the cavities 26 by a deposition process such as, for example, CVD, PECVD, or spin-coating.

Referring now to FIG. 5, there is illustrated a precursor structure vapor chamber heat spreader which is formed by bonding the top portion of the vapor chamber heat spreader shown in FIG. 4C and the bottom portion of the vapor chamber heat spreader shown in FIG. 3D together. Notably, the bonding includes aligning the top portion of the vapor chamber heat spreader and the bottom portion of the vapor chamber heat spreader such that each cavity 36 of the top portion of the vapor chamber heat spreader is aligned over one or more electrodes 16 of the bottom portion of the vapor chamber heat spreader (the aligned can be aided by aligning the second patterned dielectric layer 30B and the first patterned dielectric layer 30A), bringing the aligned top portion and the bottom portion of the vapor chamber heat spreader into intimate contact with each other, and then heating the contacted structure to facilitate bonding between the top portion of the vapor chamber heat spreader and the bottom portion of the vapor chamber heat spreader. After bonding that first semiconductor substrate 12A and second semiconductor substrate 12B are components of the semiconductor structure 12 illustrated in FIG. 1.

In some embodiments, the bonding occurs by bonding the second patterned dielectric layer 30B to the first patterned dielectric layer 30A. Such bonding forms a dielectric-to-dielectric bonded structure 30 that includes the second patterned dielectric layer 30B and the first patterned dielectric layer 30A as an integrated component present in the semiconductor structure 12. In some embodiments, the second patterned dielectric layer 30B and the first patterned dielectric layer 30A are each removed prior to bonding such that the bonding forms a semiconductor-to-semiconductor bonded structure (i.e., the semiconductor structure 12 as illustrated in FIG. 1). In either embodiment, the heating step utilized in the bonding process is typically performed at a temperature from 20° C. to 550° C. and an inert ambient such as, for example, helium and/or argon. An external pressure can be applied during the heating process that bonds the top and bottom portions together.

The precursor vapor chamber heat spreader can be processed into a vapor chamber heat spreader by revealing a surface of each of the electrically conductive via structures 14. This can be achieved utilizing a planarization process such, as for example, CMP, to thin the first semiconductor substrate 12A such that a surface of each of the electrically conductive via structures 14 is revealed.

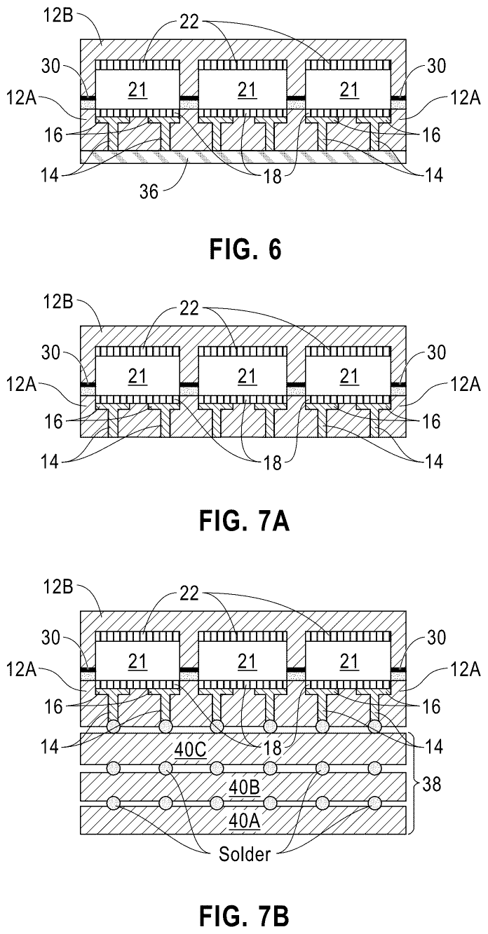

FIG. 6 illustrates an embodiment in which a vapor chamber heat spreader of the present application is in contact with an end-of-the-line (EOL) layer 36 of a microelectronic device. An assembly in accordance with the present application is thus shown in FIG. 6. The EOL layer 36 can include a semiconductor substrate including at least one semiconductor material as mentioned above, or an interlayer dielectric (ILD) layer. The semiconductor substrate can have one or more semiconductor device fabricating thereon. The ILD layer can be a component of a frontside or backside back-end-of-the-line (BEO) structure or a middle-of-the-line (MOL) structure. The ILD layer is composed of ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. The ILD layer can include various wiring regions embedded therein. The wiring regions can be composed of an electrically conductive metal or an electrically conductive metal alloy as described herein. The EOL layer 36 can be a component of a semiconductor die or semiconductor die stack.

In some embodiments the assembly shown in FIG. 6 can be formed as follow: the bottom portion of the heat spreader as shown in FIGS. 3A-3D (modified such that each electrically contact via structure 14 extends entirely through the first semiconductor substrate 12A) is formed directly on the EOL layer 36, and thereafter the top portion of the vapor chamber heat spreader as shown in FIG. 4C is bonded to the bottom portion of the vapor chamber heat spreader that is in contact with the EOL layer 36. In other embodiments the assembly shown in FIG. 6 can be formed as follow: the precursor vapor chamber heat spreader as shown in FIG. 5 is formed, followed by a step of revealing each of the electrically conductive via structures 14, followed by attaching the EOL layer 36 to the vapor chamber heat spreader utilizing a bonding process, solder balls or any like attachment method.

Referring now to FIGS. 7A-7B, there is illustrated a process flow for forming an assembly in accordance with an embodiment of the present application. Notably, FIG. 7A illustrates the precursor vapor chamber heat spreader of FIG. 5 after revealing a surface of each of the electrically conductive via structures 14. The revealing of a surface of each of the electrically conductive via structures 14 includes a planarization process as mentioned above which thins the first semiconductor substrate 12A such that a surface of each of the electrically conductive via structures 14 is revealed. The revealing process converts the precursor vapor chamber heat spreader of FIG. 5 into a vapor chamber heat spreader as illustrated in FIG. 7A and in accordance with an embodiment of the present application.

Next, and as illustrated in FIG. 7B, the vapor chamber heat spreader of FIG. 7A is attached to die stack 38A which includes a plurality of semiconductor die that are attached to each other by solder balls. Notably, and by way of one example, die stack 38 includes a first semiconductor die 40A, a second semiconductor die 40B and a third semiconductor die 40C. Solder balls are also used to electrically connect the die stack 38 to the revealed surface of each of the electrically conductive via structures 14 shown in FIG. 7A. It is noted that the solder balls can be lead containing solder balls or lead free solder balls. Notably, FIG. 7B illustrates an exemplary assembly in accordance with an embodiment of the present application. The exemplary assembly illustrated in FIG. 7B includes a microelectronic device (e.g., die stack 38) attached to a vapor chamber heat spreader (for example the vapor chamber heat spreader shown in FIG. 7A).

It is noted that although FIG. 7B illustrates solder balls for attaching the semiconductor die to each other and to attach the topmost semiconductor die to a vapor chamber heat spreader in accordance with the present application, the present application works when the attachment between the semiconductor die to each other and/or to attach the topmost semiconductor die to a vapor chamber heat spreader includes other attachment means that are well known to those skilled in the art.

Notably, FIGS. 6 and 7B illustrates an assembly in accordance with an embodiment of the present application. In an embodiment of the present application, the assembly includes a microelectronic device (e.g., the EOL layer 36 shown in FIG. 6, or the stacked die stack 38 shown in FIG. 7B) attached to a vapor chamber heat spreader (see, for example, FIGS. 1 and 5). The vapor chamber heat spreader includes vapor core 21 present in an interior of semiconductor structure 12, first hydrophobic layer 18 is located in the interior of the semiconductor structure 12 and beneath the vapor core 21, second hydrophobic layer 22 is located in the interior of the semiconductor structure 12 and above the vapor core 21, and a plurality of electrodes (i.e., electrodes 16) and a plurality of electrically conductive via structures (i.e., electrically conducive via structures 14) located in a bottom portion of the semiconductor structure 12. Each electrically conductive via structure 14 of the plurality of electrically conductive via structures is in electrical contact with, and located beneath, one of the electrodes 16 of plurality of electrodes and each electrically conductive via structure 14 extends entirely through the bottom portion of the semiconductor structure 12. In the vapor chamber heat spreader of the assembly of the present application (and as illustrated in FIG. 2) liquid is guided to hotspots generated by the microelectronic device by application of electrowetting which is controlled by each electrically connected electrode/electrically conductive via structure combination. Thus, the vapor chamber heat spreader facilitates heat spreading and heat removal from the attached microelectronic device, while having an increased dry out limit that is significantly greater than conventional vapor chambers. The increased dry out limit of the vapor chamber heat spreader of the present application is achieved by electrowetting using electrodes that are powered through the electrically conductive via structures by the microelectronic device.

In some embodiments, each of the electrodes 16 of the plurality of electrodes is in direct physical contact with the first hydrophobic layer 18.

In some embodiments, the vapor chamber heat spreader of the present application further includes dielectric layer 17 located between the first hydrophobic layer 18 and the plurality of electrodes.

In embodiments, the vapor chamber heat spreader of the present application includes a support pillar 20 present in the vapor core 21. The support pillar 20 provides structural support and can serve as a wicking aid in the vapor chamber heat spreader of the present application as described above.

In some embodiments, the second hydrophobic layer 22 is in direct physical contact with a top portion of the semiconductor structure 12. The second hydrophobic layer 22 helps in returning condensate to the bottom portion of the vapor chamber typically via the support pillars 20.

In some embodiments, the bottom portion of the semiconductor structure 12 is composed of first semiconductor substrate 12A (see, for example, FIG. 3A) and the semiconductor structure has a top portion composed of second semiconductor substrate 12B (see, for example, FIG. 4A), and the first semiconductor substrate 12A is in direct physical contact with the second semiconductor substrate 12B; such an embodiment is illustrated in FIG. 1.

In some embodiments, the bottom portion of the semiconductor structure 12 is composed of first semiconductor substrate 12A (see, for example, FIG. 3A) and the semiconductor structure 12 has a top portion composed of second semiconductor substrate 12B, and the first semiconductor substrate 12A is spaced apart from the second semiconductor substrate 12B by a dielectric-to-dielectric bonded structure 30 (See, for example, FIG. 5).

In some embodiments (see, for example, FIGS. 5 and 7B), the microelectronic device is in electrically contact with each of the electrically conductive via structures of the plurality of electrically conductive via structures of the vapor chamber heat spreader.

In some embodiments (see, for example, FIGS. 5 and 7B), the microelectronic device is bonded to the bottom portion of semiconductor structure of the vapor chamber heat spreader.

In the present application, the electrodes 16 that are present in the vapor chamber heat spreader are powered by the microelectronic device.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A vapor chamber heat spreader comprising:
a vapor core present in an interior of a semiconductor structure;
a first hydrophobic layer located in the interior of the semiconductor structure and beneath the vapor core;
a second hydrophobic layer located in the interior of the semiconductor structure and above the vapor core; and
and a plurality of electrodes and a plurality of electrically conductive via structures located in a bottom portion of the semiconductor structure, wherein each electrically conductive via structure of the plurality of electrically conductive via structures is in electrical contact with, and located beneath, one of the electrodes of plurality of electrodes and each electrically conductive via structure extends entirely through the bottom portion of the semiconductor structure.

2. The vapor chamber heat spreader of claim 1, wherein each of the electrodes of the plurality of electrodes is in direct physical contact with the first hydrophobic layer.

3. The vapor chamber heat spreader of claim 1, further comprising a dielectric layer located between the first hydrophobic layer and the plurality of electrodes.

4. The vapor chamber heat spreader of claim 1, further comprising a support pillar present in the vapor core.

5. The vapor chamber heat spreader of claim 1, wherein the plurality of electrodes and the plurality of electrically conductive via structures are composed of a same electrically conductive metal or electrically conductive metal alloy.

6. The vapor chamber heat spreader of claim 1, wherein the plurality of electrodes are composed of a first electrically conductive material, and the plurality of electrically conductive via structures are composed of a second electrically conductive material in which the second electrically conductive material is compositionally different from the first electrically conductive material.

7. The vapor chamber heat spreader of claim 1, wherein the second hydrophobic layer is in direct physical contact with a top portion of the semiconductor structure.

8. The vapor chamber heat spreader of claim 1, wherein the bottom portion of the semiconductor structure is composed of a first semiconductor substrate and the semiconductor structure has a top portion composed of a second semiconductor substrate, and the first semiconductor substrate is in direct physical contact with the second semiconductor substrate.

9. The vapor chamber heat spreader of claim 1, wherein the bottom portion of the semiconductor structure is composed of a first semiconductor substrate and the semiconductor structure has a top portion composed of a second semiconductor substrate, and the first semiconductor substrate is spaced apart from the second semiconductor substrate by a dielectric-to-dielectric bonded structure.

10. An assembly comprising:
a microelectronic device attached to a vapor chamber heat spreader, the vapor chamber heat spreader comprising:
a vapor core present in an interior of a semiconductor structure;
a first hydrophobic layer located in the interior of the semiconductor structure and beneath the vapor core;
a second hydrophobic layer located in the interior of the semiconductor structure and above the vapor core; and
a plurality of electrodes and a plurality of electrically conductive via structures located in a bottom portion of the semiconductor structure, wherein each electrically conductive via structure of the plurality of electrically conductive via structures is in electrical contact with, and located beneath, one of the electrodes of plurality of electrodes and each electrically conductive via structure extends entirely through the bottom portion of the semiconductor structure.

11. The assembly of claim 10, wherein each of the electrodes of the plurality of electrodes is in direct physical contact with the first hydrophobic layer.

12. The assembly of claim 10, wherein the vapor chamber heat spreader further comprises a dielectric layer located between the first hydrophobic layer and the plurality of electrodes.

13. The assembly of claim 10. wherein the vapor chamber heat spreader further comprises a pillar structure present in the vapor core.

14. The assembly of claim 10, wherein the second hydrophobic layer is in direct physical contact with a top portion of the semiconductor structure.

15. The assembly of claim 10, wherein the bottom portion of the semiconductor structure is composed of a first semiconductor substrate and the semiconductor structure has a top portion composed of a second semiconductor substrate, and the first semiconductor substrate is in direct physical contact with the second semiconductor substrate.

16. The assembly of claim 10, wherein the bottom portion of the semiconductor structure is composed of a first semiconductor substrate and the semiconductor structure has a top portion composed of a second semiconductor substrate, and the first semiconductor substrate is spaced apart from the second semiconductor substrate by a dielectric-to-dielectric bonded structure.

17. The assembly of claim 10, wherein the microelectronic device is in electrically contact with each electrically conductive via structure of the plurality of electrically conductive via structures of the vapor chamber heat spreader.

18. The assembly of claim 10, wherein the microelectronic device is bonded to the bottom portion of semiconductor structure of the vapor chamber heat spreader.

19. The assembly of claim 10, wherein the plurality of electrodes are powered by the microelectronic device.
